(19) United States
(12) Patent Application Publication
(10) Pub. No.: US 2026/0052664 A1
(43) Pub. Date: Feb. 19, 2026

(54) INTEGRATED CIRCUIT DEVICE AND METHOD FOR FABRICATING THE SAME

(71) Applicant: TAIWAN SEMICONDUCTOR MANUFACTURING COMPANY, LTD., Hsinchu (TW)

(72) Inventors: Dian-Sheng YU, Hsinchu City (TW); Kuo-Hua PAN, Hsinchu City (TW); Chia He CHUNG, Hsinchu City (TW)

(73) Assignee: TAIWAN SEMICONDUCTOR MANUFACTURING COMPANY, LTD., Hsinchu (TW)

(21) Appl. No.: 18/806,427

(22) Filed: Aug. 15, 2024

(51) Int. Cl. H10B 10/00

(52) U.S. Cl. CPC H10B 10/12

(57) ABSTRACT

An integrated circuit device includes a first memory cell, a second memory cell, an interconnect structure over the first and second memory cells. The interconnect structure includes first to third metallization layers. The first metallization layer includes first and second word lines electrically connected to the first and second memory cells, respectively. The second metallization layer is above the first metallization layer. The second metallization layer includes third and fourth word lines electrically connected to the first and second word lines, respectively. The third metallization layer is above the second metallization layer. The third metallization layer includes a fifth word line electrically connected to the third word line. The first to fifth word lines extend substantially along a direction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of an integrated circuit device including a static random-access memory (SRAM) array according to some embodiments of the present disclosure.

FIG. 1B is a circuit diagram of a SRAM cell according to some embodiments of the present disclosure.

FIGS. 2A and 2B are cross-sectional views of an integrated circuit device at intermediate stages of a fabrication process according to some embodiments of t he present disclosure.

FIGS. 3A and 3B are schematic views of a MLI structure of an integrated circuit device according to some embodiments of t he present disclosure.

FIG. 3C is an enlarged view of a portion of FIG. 3A.

FIGS. 4A-4C are top views of metallization layers of an integrated circuit device according to some embodiments of t he present disclosure.

FIGS. 5A-5C are top views of metallization layers of an integrated circuit device according to some embodiments of t he present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.”

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 130 rees or at other orientations) and the spatially relative descriptors used herein may likewise be interpreted accordingly.

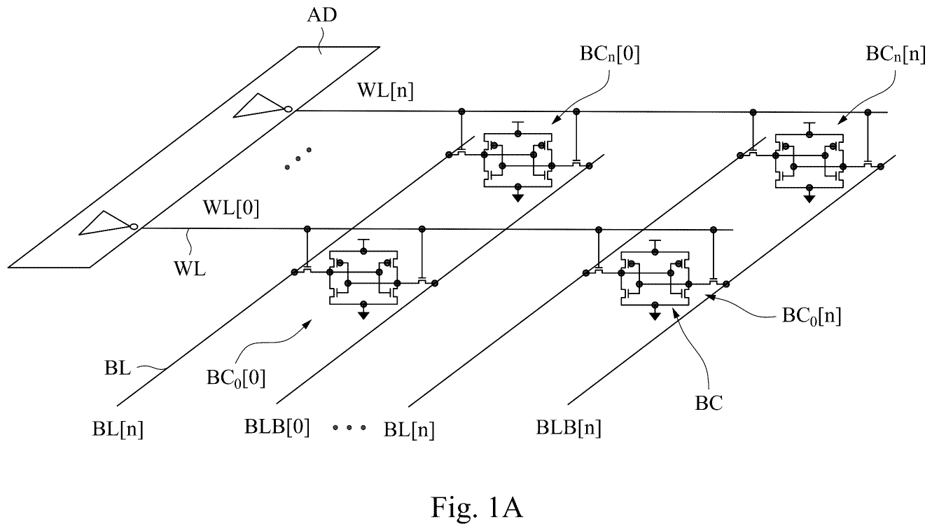

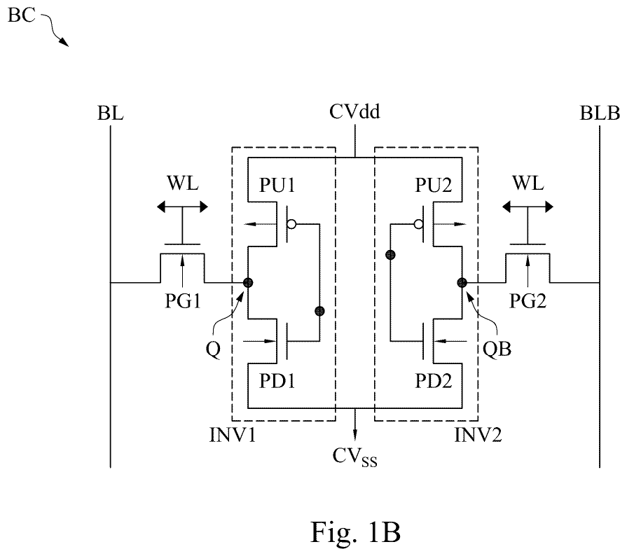

FIG. 1A is a circuit diagram of an integrated circuit device including a static random-access memory (SRAM) array according to some embodiments of the present disclosure. The integrated circuit device includes plural SRAM cells BC arranged in an array, plural bit lines BL, plural bit line bars BLB, and plural word lines WL. Each of the SRAM cells BC includes plural transistors 140 connected to one of the bit lines BL, one of the bit line bars BLB, and one of the word lines WL. For example, the illustrated SRAM cells BC has six transistors, which are metal oxide semiconductor field effect transistor (MOSFET).

FIG. 1B is a circuit diagram of a SRAM cell BC according to some embodiments of the present disclosure. SRAM cell BC includes pull-up transistors PU1 and PU2, which are p-type Metal-Oxide-Semiconductor (PMOS) transistors, and pull-down transistors PD1 and PD2 and pass-gate transistors PG1 and PG2, which are n-type Metal-Oxide-Semiconductor (NMOS) transistors. The gates of the pass-gate transistors PG1 and PG2 are controlled by a word line WL that determines whether SRAM cell BC is selected or not. A latch formed of the pull-up transistors PU1 and PU2 and pull-down transistors PD1 and PD2 stores a bit, wherein the complementary values of the bit are stored in storage data nodes Q and QB. The stored bit can be written into, or read from, SRAM cell BC through complementary bit lines including a bit line BL and a bit line bar BLB. SRAM cell BC is powered through a positive power supply node CVdd that has a positive power supply voltage. SRAM cell BC is also connected to a power supply voltage node CVss, which may be an electrical ground. Transistors PU1 and PD1 form a first inverter INV1. Transistors PU2 and PD2 form a second inverter INV2. The first and second inverters INV1 and INV2 are cross-latched. For example, the input of the first inverter INV1 (e.g., gates of the transistors PU1 and PD1) is connected to the output of the second inverter INV2 (e.g., drains of the transistors PU2 and PD2), and the output of the first inverter INV1 (e.g., drains of the transistors PU1 and PD1) is connected to the input of the second inverter INV2 (e.g., gates of the transistors PU2 and PD2). The input of the first inverter INV1 is also connected to the transistor PG2. The output of the first inverter is also connected to the transistor PG1.

The sources of the pull-up transistors PU1 and PU2 are connected to positive power supply node CVdd. The sources of the pull-down transistors PD1 and PD2 are connected to the power supply voltage node CVss. The gates of the transistors PU1 and PD1 are connected to the drains of transistors PU2 and PD2, which form a connection node that is referred to as storage data node QB. The gates of transistors PU2 and PD2 are connected to the drains of transistors PU1 and PD1, which form a connection node is referred to as storage data node Q. A source/drain region of the pass-gate transistor PG1 is connected to the bit line BL. A source/drain region of the pass-gate transistor PG2 is connected to the bit line bar BLB.

Reference is made back to FIG. 1A. For illustration, the word lines WL are annotated as word lines WL[0] to WL[n], the bit lines BL are annotated as bit lines BL[0] to BL[n], and the bit line bars BL are annotated as bit line bars BLB[0] to BLB[n]. The SRAM cells BC are arrayed and respectively annotated as SRAM cells BC₀[0] to BC₀[n] and SRAM cells BCₙ[0] to BCₙ[n] in the drawings. An address decoder AD is disposed at a side of the array of SRAM cells BC. The address decoder AD is connected with the word lines WL, e.g., from the word line WL[0] to the word line WL[n]. However, for the configuration of the SRAM array, a word line resistance may increase as a distance from the SRAM cell BC to the address decoder AD increases, thereby influencing the word line signal transmitted to the SRAM cell BC. As a result, the word line signal for the SRAM cells BC₀[n] or BCₙ[n] far away from the address decoder AD is different from the word line signal for the SRAM cells BC₀[0] or BCₙ[0] near the address decoder AD since they faces different resistances and RC relay. The SRAM 6T architectures for chip memory is designed with word line resistance loading limit for slew rate and chip access time performance.

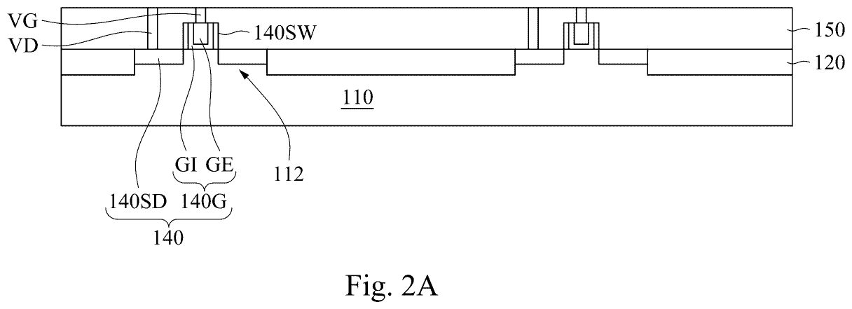

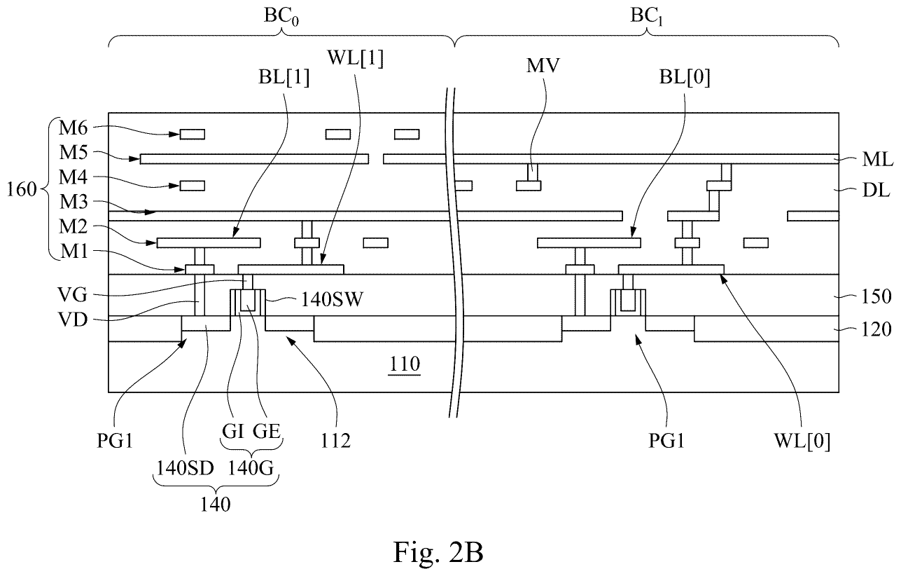

FIGS. 2A and 2B are cross-sectional views of an integrated circuit device at intermediate stages of a fabrication process according to some embodiments of t he present disclosure. It is understood that additional steps may be provided before, during, and after the steps shown in FIGS. 2A and 2B, and some of the steps described below can be replaced or eliminated for additional embodiments of the method. The order of the operations/processes may be interchangeable.

Reference is made to FIG. 2A. In some embodiments, a substrate 110 is provided. The substrate 110 may comprise a substantially monocrystalline material, for example, bulk silicon. In some other embodiments, the substrate 110 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 110 may comprise an active layer of a semiconductor-on-insulator (SOI) substrate. An SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Other substrates, such as multi-layered or gradient substrates, may also be used.

In some embodiments, one or more transistors 140 are formed on chip regions of the substrate 110. In the depicted embodiments, the transistors 140 are fin field-effect transistors (FinFET) that are three-dimensional metal oxide semiconductor field effect transistor (MOSFET) structure formed in fin-like strips of semiconductor protrusions referred to as fins 112. The cross-section shown in FIG. 2A is taken along a longitudinal axis of the fin 112 in a direction parallel to the direction of the current flow between the source/drain regions 140SD. The fin 112 may be formed by patterning the substrate 110 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 112 by etching a trench into the substrate 110 using, for example, reactive ion etching (RIE). FIG. 2A illustrates a single fin 112, although the substrate 110 may comprise any number of fins. In some other embodiments, the transistors 140 can be planar transistors or gate-all-around (GAA) transistors. The GAA transistor may be fabricated by channel stacking techniques, and stacked nanosheet (NS) can enhance the on-current (Iₒₙ) at fixed footprint.

STI regions 120 are formed on opposing sidewalls of the fin 112 as illustrated in FIG. 2A. STI regions 120 may be formed by depositing one or more dielectric materials (e.g., silicon oxide) to completely fill the trenches around the fins and then recessing the top surface of the dielectric materials. The dielectric materials of the STI regions 120 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 120 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 120 such that an upper portion of fins 112 protrudes from surrounding insulating STI regions 120. In some cases, the patterned hard mask used to form the fins 112 may also be removed by the planarization process.

In some embodiments, a gate structure 140G of the FinFET transistor 140 illustrated in FIG. 2A is a high-k, metal gate (HKMG) gate structure that may be formed using a gate-last process flow. In a gate-last process flow, a sacrificial dummy gate structure (not shown) is formed after forming the STI regions 120. The dummy gate structure may comprise a dummy gate dielectric, a dummy gate electrode, and a hard mask. First a dummy gate dielectric material (e.g., silicon oxide, silicon nitride, or the like) may be deposited. Next, a dummy gate material (e.g. amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 120. As described in greater detail below, the dummy gate structure may be replaced by the HKMG gate structure 140G as illustrated in FIG. 2A. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 2A, source/drain regions 140SD and spacers 140SW of the transistor 140 are formed, for example, self-aligned to the dummy gate structures. Spacers 140SW may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 140SW along the sidewalls of the dummy gate structures extending laterally onto a portion of the surface of the fin 112.

Source/drain regions 140SD are semiconductor regions in direct contact with the semiconductor fin 112. In some embodiments, the source/drain regions 140SD may comprise heavily-doped regions and relatively lightly-doped drain extensions, or LDD regions. Generally, the heavily-doped regions are spaced away from the dummy gate structures using the spacers 140SW, whereas the LDD regions may be formed prior to forming spacers 140SW and, hence, extend under the spacers 140SW and, in some embodiments, extend further into a portion of the semiconductor fin 112 below the dummy gate structure. The LDD regions may be formed, for example, by implanting dopants (e.g., As, P, B, In, or the like) using an ion implantation process.

The source/drain regions 140SD may comprise an epitaxially grown region. For example, after forming the LDD regions, the spacers 140SW may be formed and, subsequently, the heavily-doped source and drain regions may be formed self-aligned to the spacers 140SW by first etching the fins to form recesses, and then depositing a crystalline semiconductor material in the recess by a selective epitaxial growth (SEG) process that may fill the recess and may extend further beyond the original surface of the fin 112 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of dopants may be introduced into the heavily-doped source and drain regions SD either in situ during SEG, or by an ion implantation process performed after the SEG, or by a combination thereof.

Once the source/drain regions 140SD are formed, a first interlayer dielectric (ILD) layer (e.g., lower portion of the ILD layer 150) is deposited over the source/drain regions 140SD. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer. The HKMG gate structures 140G, illustrated in FIG. 2A, may then be formed by first removing the dummy gate structures using one or more etching techniques, thereby creating recesses between respective spacers 140SW. Next, a replacement gate dielectric layer GI comprising one more dielectrics, followed by a replacement gate metal layer GE comprising one or more metals, are deposited to completely fill the recesses. Excess portions of the gate dielectric layer GI and the gate metal layer GE may be removed from over the top surface of first ILD using, for example, a CMP process. The resulting structure, as illustrated in FIG. 2A, may include remaining portions of the gate dielectric layer GI and the gate metal layer GE inlaid between respective spacers 140SW.

The gate dielectric layer GI includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer GE may be a multilayered metal gate stack comprising a barrier layer, a work function layer, and a gate-fill layer formed successively on top of gate dielectric layer GI. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

After forming the HKMG gate structure 140G, a second ILD layer (e.g., upper portion of the ILD layer 150) is deposited over the first ILD layer, and these ILD layers are in combination referred to as the ILD layer 150, as illustrated in FIG. 2A. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, PVD, ALD, PEALD, PECVD, SACVD, FCVD, spin-on, and/or the like, or a combination thereof.

The contact plugs VD and VG may be formed in the ILD layer 150 using photolithography, etching and deposition techniques. For example, a patterned mask may be formed over the ILD layer 150 and used to etch openings that extend through the ILD layer 150 to expose the gate structure 140G as well as the source/drain regions 140SD. Thereafter, conductive liner may be formed in the openings in the ILD layer 150. Subsequently, the openings are filled with a conductive fill material. The liner comprises barrier metals used to reduce out-diffusion of conductive materials from the contact plugs VD and VG into the surrounding dielectric materials. In some embodiments, the liner may comprise two barrier metal layers. The first barrier metal comes in contact with the semiconductor material in the source/drain regions 140SD and may be subsequently chemically reacted with the heavily-doped semiconductor in the source/drain regions 140SD to form a low resistance ohmic contact, after which the unreacted metal may be removed. For example, if the heavily-doped semiconductor in the source/drain regions 140SD is silicon or silicon-germanium alloy semiconductor, then the first barrier metal may comprise Ti, Ni, Pt, Co, other suitable metals, or their alloys, and may form silicide with the source/drain regions SD. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD layer 150. The resulting conductive plugs extend into the ILD layer 150 and constitute contact plugs VD and VG making physical and electrical connections to the gates or source/drain nodes of electronic devices, such as the tri-gate FinFET transistor 140 illustrated in FIG. 2A.

Reference is made to FIG. 2B. A multilayer interconnection (MLI) structure 160 may be formed on the substrate 110. The MLI structure 160 may have include a plurality of metallization layers, such as the metallization layer M1-M6. The number of metallization layers may vary according to design specifications of the integrated circuit. Only six metallization layers are illustrated in FIG. 2B for the sake of simplicity.

The metallization layers M1-M6 each comprise an inter-metal dielectric (IMD) layer DI. The metallization layers M1-M6 comprise one or more horizontal interconnects, such as metal lines ML, respectively extending horizontally or laterally in the IMD layers DI and vertical interconnects, such as conductive vias MV, respectively extending vertically in the IMD layers DI. In some embodiments, some of the metal lines ML in the bottommost metallization layer M1 are respectively in contact with the contact plug VD to make electrical connection to the source/drain region 140SD. And, some of the metal lines ML in the bottommost metallization layer M1 are respectively in contact with the contact plug VG to make electrical connection to the gate structure 140G.

The metal lines ML and metal vias MV can be formed using, for example, a single damascene process, a dual damascene pr ocess, the like, or combinations thereof. In some embodiments, the IMD layers DI may include low-k dielectric materials having k values, for example, lower than about 4.0 or even 2.0 disposed between such conductive features. In some embodiments, the IMD layers DI may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The metal lines and vias ML and MV may comprise metal materials such as copper, aluminum, tungsten, combinations thereof, or the like. In some embodiments, the metal lines and vias ML and MV may further comprise one or more barrier/adhesion layers (not shown) to protect the respective IMD layers DI from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like. In some embodiments, the metal lines ML and metal vias MV in combination may be referred to as a metallization pattern. In the context, the metal lines ML and metal vias MV may also be referred to as conductive features.

Reference is made to FIGS. 1A, 1B, and 2B. The transistors 140 in FIG. 2B may serve as the pull-up transistors PU1 and PU2, the pull-down t ransistors PD1 and PD2, and the pass-gate transistor PG1 and PG2 in SRAM cells BC in FIGS. 1A and 1B. And, the metal lines ML and/or the metal vias MV of the metallization layers M1-M6 in FIG. 2B may serve as the bit lines BL, the bit line bars BLB, and the word lines WL.

For example, as annotated in FIG. 2B, regions of two SRAM cells BC₀ and BC₁ are indicated, and the transistors 140 in the regions of the SRAM cells BC₀ and BC₁ may respectively serve as the pass-gate transistor PG1 of the SRAM cell BC₀ and the pass-gate transistor PG1 of the SRAM cell BC₁. In the present embodiments, some metal lines ML of the metallization layers M1 and M5 may be electrically connected with each other and serve as the word line WL[0] electrically connected with the gate structure 140G of the pass-gate transistor PG1 of the SRAM cell BC₀. And, some metal lines ML of the metallization layers M1 and M3 may be electrically connected with each other and serve as the word line WL[1] electrically connected with the gate structure 140G of the pass-gate transistor PG1 of the SRAM cell BC₁. Some metal lines ML of the metallization layer M2 may serve as the bit lines BL[0] and BL[1] respectively electrically connected with the source/drain regions 140SD of the pass-gate transistor PG1 of the SRAM cell BC₀ and the pass-gate transistor PG1 of the SRAM cell BC₁.

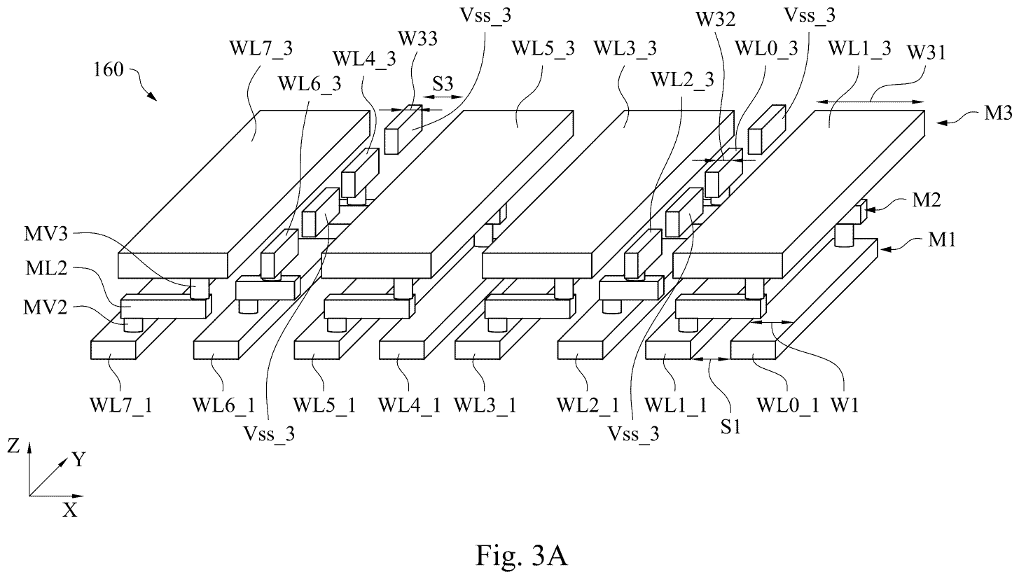

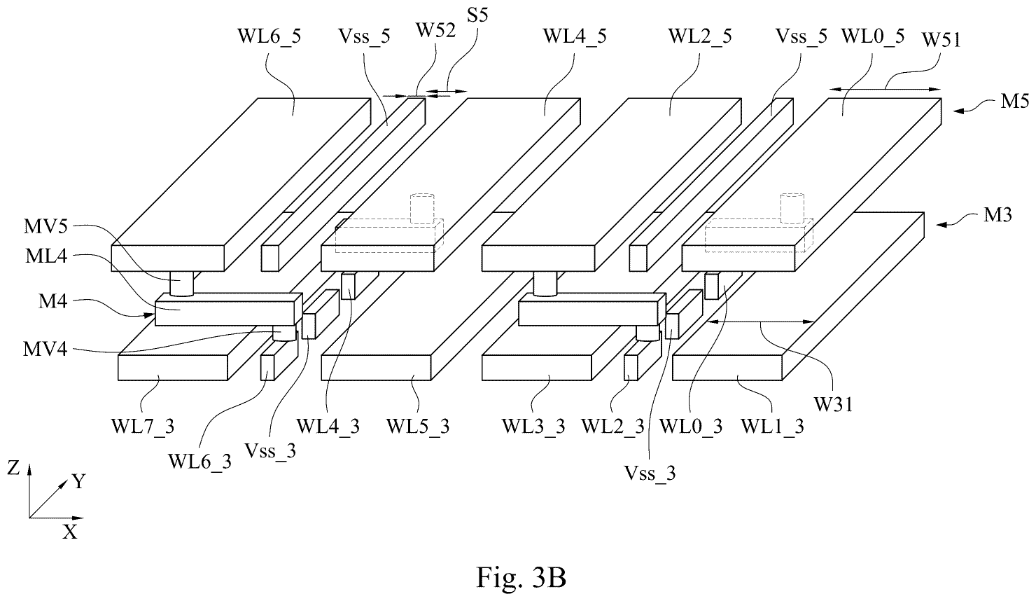

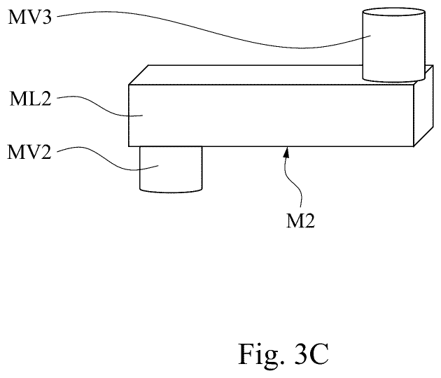

FIGS. 3A and 3B are schematic views of an MLI structure of an integrated circuit device according to some embodiments of the present disclosure. FIG. 3C is an enlarged view of a portion of FIG. 3A. The MLI structure 160 of the integrated circuit device may include metallization layers M1-M6 stacked one over another along a direction Z. In FIGS. 3A and 3B, a byte including eight SRAM cells and eight word lines is shown.

Reference is made to FIG. 3A. The metallization layer M1 may include metal lines WL0_1, WL1_1, WL2_1, WL3_1, WL4_1, WL5_1, WL6_1, and WL7_1. The metal lines WL0_1, WL1_1, WL2_1, WL3_1, WL4_1, WL5_1, WL6_1, and WL7_1 may extend along a direction Y, and spaced apart from each other along a direction X. The directions X, Y, and Z are orthogonal to each other. In some embodiments, the metal lines WL0_1, WL1_1, WL2_1, WL3_1, WL4_1, WL5_1, WL6_1, and WL7_1 may substantially have a width W1, and every adjacent two of the metal lines WL0_1, WL1_1, WL2_1, WL3_1, WL4_1, WL5_1, WL6_1, and WL7_1 may be substantially spaced apart from each other by a space S1. In some embodiments, the widths W1 of the metal lines WL0_1, WL1_1, WL2_1, WL3_1, WL4_1, WL5_1, WL6_1, and WL7_1 may be substantially the same, and the spaces S1 of the metal lines WL0_1, WL1_1, WL2_1, WL3_1, WL4_1, WL5_1, WL6_1, and WL7_1 may be substantially the same.

The metallization layer M3 may include metal lines WL1_3, WL3_3, WL5_3, and WL7_3, and metal pads WL0_3, WL2_3, WL4_3, WL6_3, and Vss_3. The metal lines WL1_3, WL3_3, WL5_3, and WL7_3 may extend along the direction Y, and spaced apart from each other along the direction X. Lengths of the metal pads WL0_3, WL2_3, WL4_3, WL6_3, and Vss_3 along the direction Y are less than lengths of the metal lines WL1_3, WL3_3, WL5_3, and WL7_3. The metal pads WL0_3, WL2_3, WL4_3, WL6_3, and Vss_3 may also be referred to as metal islands in the present embodiments.

In the present embodiments, the metal lines WL1_3, WL3_3, WL5_3, and WL7_3 may substantially have a width W31 greater than the width W1, and the metal pads WL0_3, WL2_3, WL4_3, and WL6_3 may substantially have a width W32 less than the width W1. And, every adjacent two of the metal lines WL1_3, WL3_3, WL5_3, and WL7_3 and the metal pads WL0_3, WL2_3, WL4_3, WL6_3, and Vss_3 may be substantially spaced apart from each other by a space S3, which may be greater than the space S1. In some embodiments, the widths W31 of the metal lines WL1_3, WL3_3, WL5_3, and WL7_3 may be substantially the same, the widths W32 of the metal pads WL0_3, WL2_3, WL4_3, and WL6_3 may be substantially the same, and the spaces S3 may be substantially the same.

The metal pads WL0_3 and WL2_3 and some metal pads Vss_3 may be substantially aligned with each other along the direction Y, in which at least one of the metal pads Vss_3 is interposed between the metal pads WL0_3 and WL2_3 along the direction Y. The metal pads WL0_3 and WL2_3 and the metal pads Vss_3 may be disposed between the metal lines WL1_3 and WL3_3. And, the metal pads WL4_3 and WL6_3 and some metal pads Vss_3 may be substantially aligned with each other along the direction Y, in which at least one of the metal pads Vss_3 is interposed between the metal pads WL4_3 and WL6_3 along the direction Y. The metal pads WL4_3 and WL6_3 and the metal pads Vss_3 may be disposed between the metal lines WL5_3 and WL7_3. The metal pads Vss_3 may substantially have a width W33 less than the width W1. The width W33 of the metal pads Vss_3 may be substantially the same. In some embodiments, the width W33 of the metal pads Vss_3 may be substantially equal to the widths W32 of the metal pads WL0_3, WL2_3, WL4_3, and WL6_3.

In some embodiments of the present disclosure, the metal lines WL1_3, WL3_3, WL5_3, and WL7_3 and the metal pads WL0_3, WL2_3, WL4_3, and WL6_3 are respectively electrically connected to the metal lines WL1_1, WL3_1, WL5_1, and WL7_1 and the metal lines WL0_1, WL2_1, WL4_1, and WL6_1 through the metal via MV2, the metal lines ML2, and the metal vias MV3. The metal lines ML2 are of the metallization layer M2 between the metallization layers M1 and M3. The metal vias MV2 connect the metal lines ML2 of the metallization layer M2 to the metal lines of the metallization layer M1 (e.g., the metal lines WL0_1, WL1_1, WL2_1, WL3_1, WL4_1, WL5_1, WL6_1, and WL7_1). The metal vias MV3 connect the metal lines/pads of the metallization layer M3 (e.g., the metal lines WL1_3, WL3_3, WL5_3, and WL7_3 and the metal pads WL0_3, WL2_3, WL4_3, and WL6_3) to the metal lines ML2 of the metallization layer M2, respectively. The metal vias MV3 may be misaligned with the metal vias MV2 in the direction Z in the present embodiments. In some other embodiments, the metal vias MV3 may be aligned with the metal vias MV2 in the direction Z in the present embodiments.

Reference is made to FIG. 3B. The metallization layer M5 may include metal lines WL0_5, WL2_5, WL4_5, and WL6_5, and Vss_5. The metal lines WL0_5, WL2_5, WL4_5, and WL6_5, and Vss_5 may extend along the direction Y, and spaced apart from each other along the direction X. In the present embodiments, the metal lines WL0_5, WL2_5, WL4_5, and WL6_5 may substantially have a width W51 greater than the width W1. And, every adjacent two of the metal lines WL0_5, WL2_5, WL4_5, and WL6_5 may be substantially spaced apart from each other by a space S5, which may be greater than the space S1. In some embodiments, the widths W51 of the metal lines WL0_5, WL2_5, WL4_5, and WL6_5 may be substantially the same, and the spaces S5 of the metal lines WL0_5, WL2_5, WL4_5, and WL6_5 may be substantially the same.

The metal lines Vss_5 may substantially have a width W52 less than the width W1. The width W52 of the metal lines Vss_5 may be substantially the same. The metal lines Vss_5 may be disposed between the metal lines WL0_5 and WL2_5 and between the metal lines WL4_5 and WL6_5.

In some embodiments of the present disclosure, the metal lines WL0_5, WL2_5, WL4_5, and WL6_5 are electrically connected to the metal pads WL0_3, WL2_3, WL4_3, and WL6_3, through the metal via MV4, the metal lines ML4, and the metal vias MV5. The metal lines ML4 are of the metallization layer M4 between the metallization layers M3 and M5. The metal vias MV4 connect the metal lines ML4 of the metallization layer M4 to the metal lines of the metallization layer M3 (e.g., the metal pads WL0_3, WL2_3, WL4_3, and WL6_3). The metal vias MV5 connect the metal lines of the metallization layer M5 (e.g., the metal lines WL0_5, WL2_5, WL4_5, and WL6_5) to the metal lines ML4 of the metallization layer M4. Through the configuration, a world line design utilizes a hybrid structure where half of the top word line is made of the metallization layer M5 and the other half of the top word line is made of the metallization layer M5, thereby overcoming the limitations of high world line resistance and well power management as technology scaling.

In some embodiments, the metal lines Vss_5 can be electrically connected to the metal pads Vss_3 through the metal via MV4, the metal lines ML4, and the metal vias MV5. The metal lines Vss_5 and the metal pads Vss_3 are electrically connected with a reference power source, and can be referred to as power rails in the context. In some embodiments, the metallization layer M5 may include two power rails (e.g., two metal lines Vss_5) for each byte.

In some embodiments of the present disclosure, by using the metallization layers M1 and M3 to form the odd word lines, and using the metallization layers M1 and M5 to form the even word lines, the word line resistance is reduced, thereby improving the power management as technology scaling. This word line metal resistance design window is improved to achieve high speed applications for semiconductor technologies.

In some embodiments, as shown in FIG. 3B, the metal lines WL0_5, WL2_5, WL4_5, and WL6_5 are vertically aligned with the metal pads WL0_3, WL2_3, WL4_3, and WL6_3, respectively, along the direction Z. In some embodiments, the width W51 may be substantially equal to the width W31. In some embodiments, as shown in FIG. 3B, one of the metal lines Vss_5 is vertically aligned with the metal pads WL0_3 and WL2_3 and some metal pads Vss_3 along the direction Z, and another one of the metal lines Vss_5 is vertically aligned with the metal pads WL4_3 and WL6_3 and some metal pads Vss_3 along the direction Z.

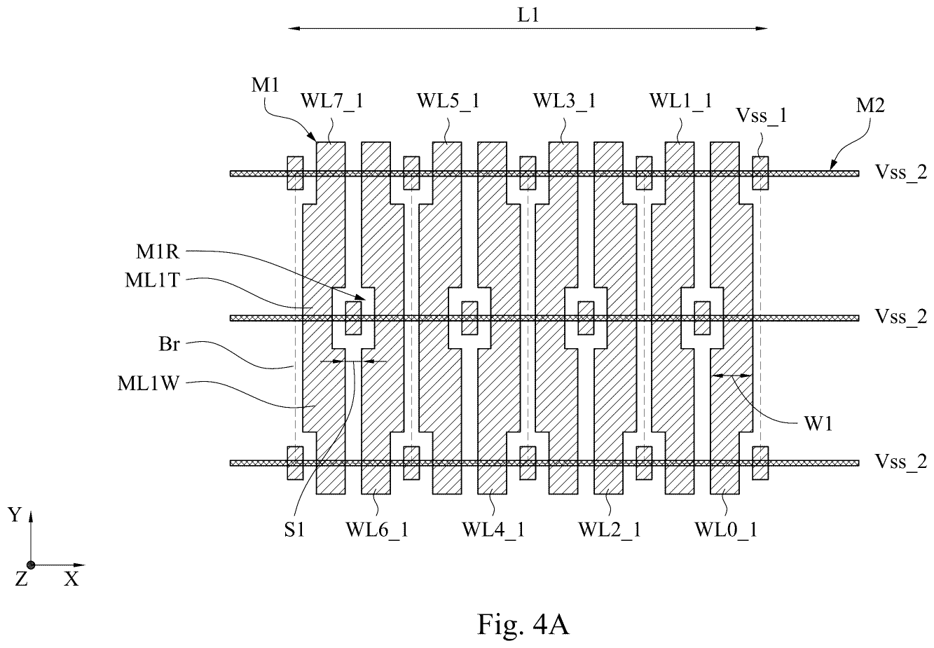

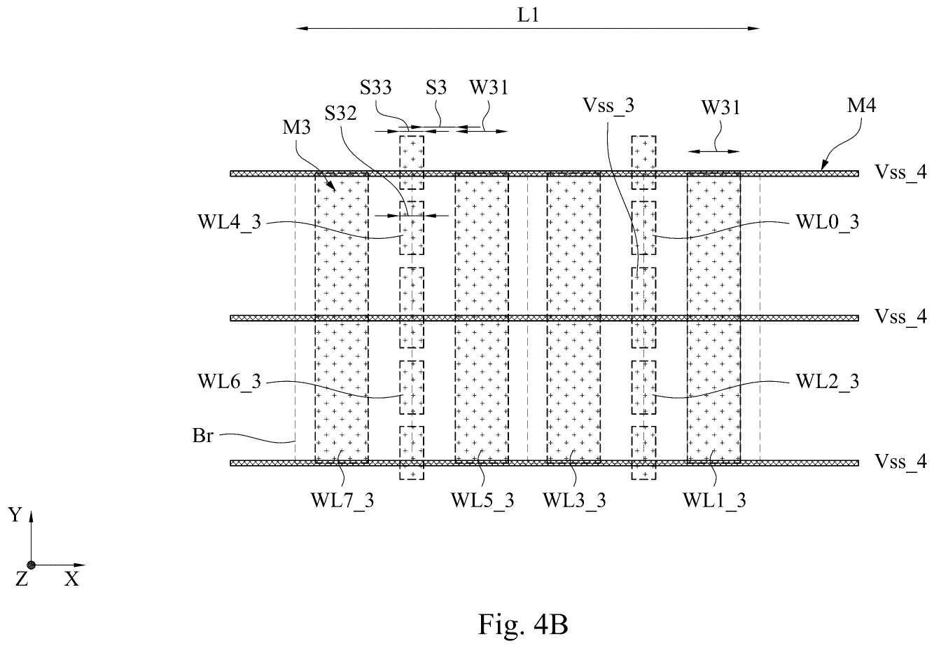

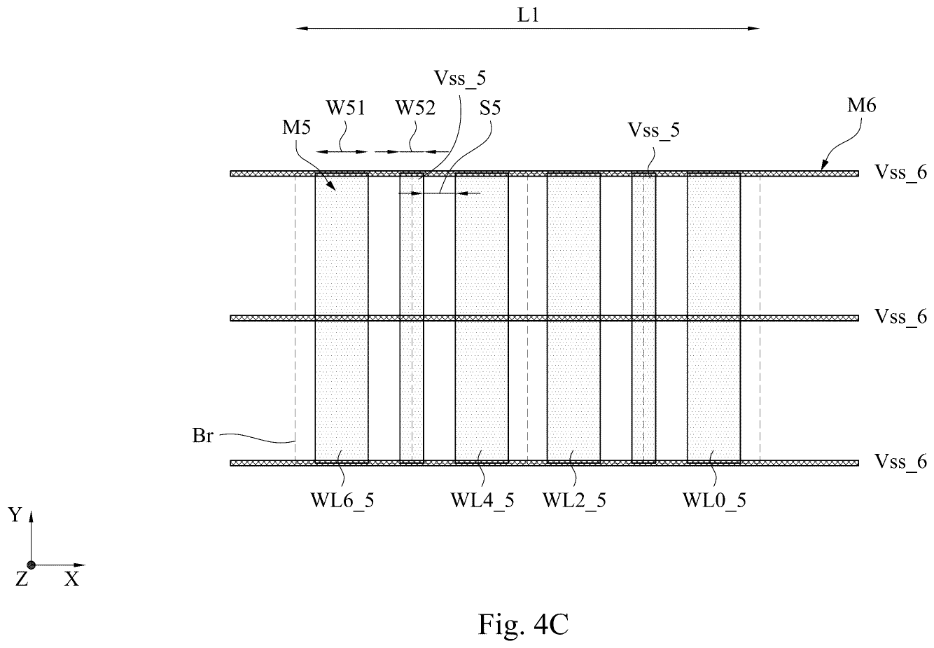

FIGS. 4A-4C are top views of metallization layers M1-M6 of an integrated circuit device according to some embodiments of t he present disclosure. Details of the present embodiments are similar to those illustrated in FIGS. 3A and 3B, except that the metallization layer M1 may have metal lines Vss_1. In FIGS. 4A-4C, the boundary Br may indicate an area of the unit cell, in which a layout can be formed by repeated the unit cells. And, the unit cell includes two SRAM cells. In FIGS. 4A-4C, a byte including eight SRAM cells and eight word lines is depicted by four unit cells. The byte may have a length L1 along the direction X, in which the length L1 may be substantially equal to eight times a cell poly pitch. The cell poly pitch is a pitch between adjacent two gate lines/structures.

Reference is made to FIG. 4A. The metallization layer M1 may include metal lines WL0_1, WL1_1, WL2_1, WL3_1, WL4_1, WL5_1, WL6_1, and WL7_1 and metal lines Vss_1, which extend substantially along the direction Y. The metallization layer M2 may include metal lines Vss_2, which extend substantially along the direction X. The metal lines Vss_1 are electrically connected to the metal lines Vss_2. In FIG. 4A, the metal lines WL0_1, WL2_1, WL4_1, and WL6_1 are mirror symmetric to the metal lines WL1_1, WL3_1, WL5_1, and WL7_1, respectively. Each of the metal lines WL0_1, WL1_1, WL2_1, WL3_1, WL4_1, WL5_1, WL6_1, and WL7_1 may have plural recesses M1R facing the metal lines Vss_1. Stated differently, each of the metal lines WL0_1, WL1_1, WL2_1, WL3_1, WL4_1, WL5_1, WL6_1, and WL7_1 may have thinner segments ML1T adjacent to the metal lines Vss_1 and wider segments ML1W connected between the thinner segments ML1T. As shown in FIG. 4A, a width of the wider segments ML1W is greater than a width of the thinner segments ML1T.

Reference is made to FIG. 4B. The metallization layer M3 may include metal lines WL1_3, WL3_3, WL5_3, and WL7_3 extending substantially along the direction Y and metal pads WL0_3, WL2_3, WL4_3, WL6_3, and Vss_3. The metallization layer M4 may include metal lines Vss_4, which extend substantially along the direction X. The metal pads Vss_3 are electrically connected with the metal lines Vss_4 and the metal lines Vss_2 (referring to FIG. 4A).

Reference is made to FIG. 4C. The metallization layer M5 may include metal lines WL0_5, WL2_5, WL4_5, WL6_5, and Vss_5, which extend substantially along the direction Y. The metallization layer M6 may include metal lines Vss_6, which extend substantially along the direction X. The metal lines Vss_5 are electrically connected with the metal lines Vss_6 and the metal lines Vss_4 (referring to FIG. 4B). In FIGS. 4A-4C, the metal lines Vss_2, Vss_4, and Vss_6 in the metallization layers M2, M4, and M6 may provide well power mesh of chip in hybrid M3/M5 lines WL scheme. And, the metal lines Vss_2, Vss_4, and Vss_6 may be electrically connected to each other through the metal lines Vss_1, the metal pads Vss_3, the metal lines Vss_5 and the metal vias MV1-MV5. Other details of the present embodiments are similar to those illustrated above, and therefore not repeated herein.

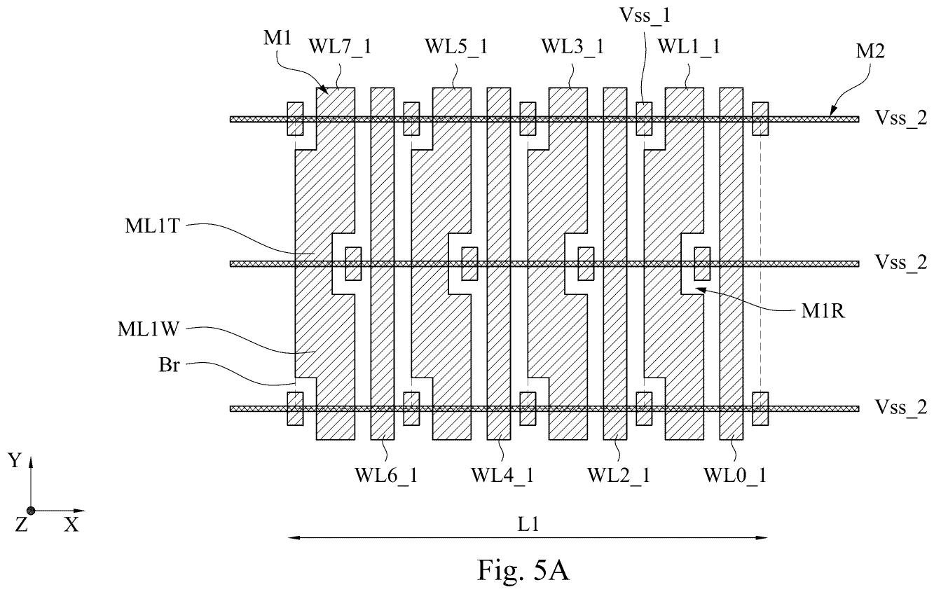

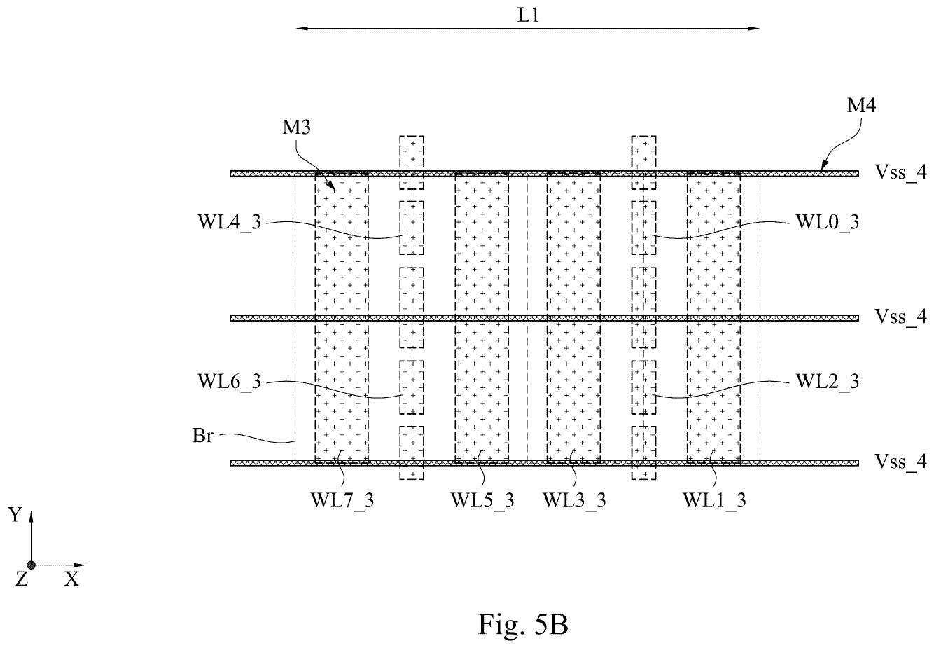

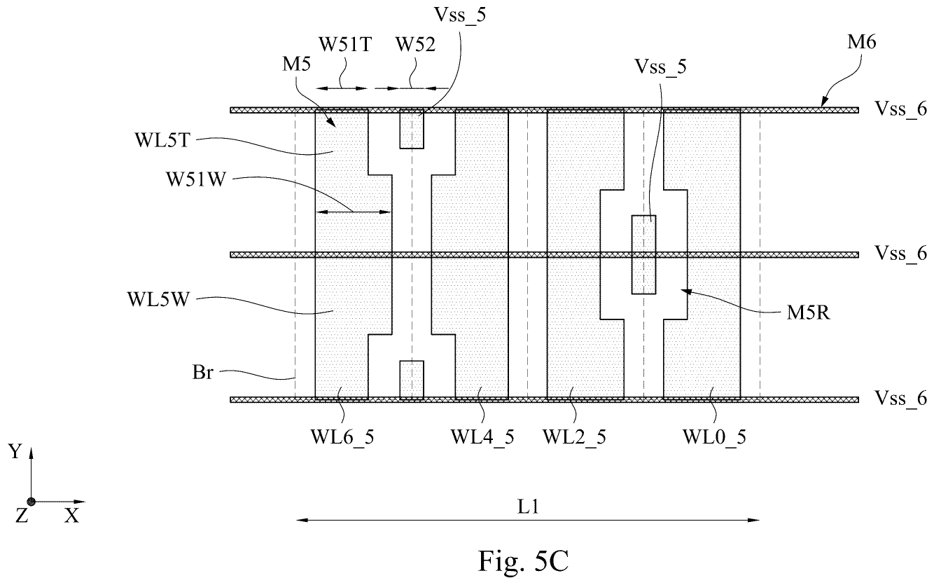

FIGS. 5A-5C are top views of metallization layers of an integrated circuit device according to some embodiments of t he present disclosure. Details of the present embodiments are similar to those illustrated in FIGS. 4A-4C, except that even word lines of the metallization layer M1 have a different configuration from odd word lines of the metallization layer M1, and the word lines of the metallization layer M6 have a jog scheme. In FIGS. 5A-5C, the boundary Br may indicate an area of the unit cell, in which a layout can be formed by repeated the unit cells. And, the unit cell includes two SRAM cells. In FIGS. 4A-4C, a byte including eight SRAM cells and eight word lines is depicted by four unit cells.

Reference is made to FIG. 5A. The metallization layer M1 may include metal lines WL0_1, WL1_1, WL2_1, WL3_1, WL4_1, WL5_1, WL6_1, and WL7_1 and metal lines Vss_1, which extend substantially along the direction Y. The metallization layer M2 may include metal lines Vss_2, which extend substantially along the direction X. The metal lines Vss_1 are electrically connected to the metal lines Vss_2. In FIG. 5A, the metal lines WL0_1, WL2_1, WL4_1, and WL6_1 are asymmetric to the metal lines WL1_1, WL3_1, WL5_1, and WL7_1, respectively. Each of the metal lines WL1_1, WL3_1, WL5_1, and WL7_1 may have plural recesses M1R facing the metal lines Vss_1. Stated differently, each of the metal lines WL1_1, WL3_1, WL5_1, and WL7_1 may have thinner segments ML1T adjacent to the metal lines Vss_1 and wider segments ML1W connected between the thinner segments ML1T. As shown in FIG. 5A, a width of the wider segments ML1W is greater than a width of the thinner segments ML1T. Each of the metal lines WL0_1, WL2_1, WL4_1, and WL6_1 may be straight lines having substantially straight sidewalls extending substantially along the direction Y.

Reference is made to FIG. 5B. As aforementioned, the metallization layer M3 may include metal lines WL1_3, WL3_3, WL5_3, and WL7_3 extending substantially along the direction Y and metal pads WL0_3, WL2_3, WL4_3, WL6_3, and Vss_3. The metallization layer M4 may include metal lines Vss_4, which extend substantially along the direction X. The metal pads Vss_3 are electrically connected with the metal lines Vss_4 and the metal lines Vss_2 (referring to FIG. 5A).

Reference is made to FIG. 5C. As aforementioned, the metallization layer M5 may include metal lines WL0_5, WL2_5, WL4_5, WL6_5, and Vss_5, which extend substantially along the direction Y. The metallization layer M6 may include metal lines Vss_6, which extend substantially along the direction X. The metal lines Vss_5 are electrically connected with the metal lines Vss_6 and the metal lines Vss_4 (referring to FIG. 5B).

In the present embodiments, the metal lines WL0_5, WL2_5, WL4_5, WL6_5, and Vss_5 have a jog scheme. For example, e ach of the metal lines WL0_5, WL2_5, WL4_5, and WL6_5, may have plural recesses M5R facing the metal lines Vss_5. Stated differently, each of the metal lines WL0_5, WL2_5, WL4_5, and WL6_5 may have thinner segments ML5T adjacent to the metal lines Vss_5 and wider segments ML5W connected between the thinner segments ML5T. As shown in FIG. 5C, a width W51W of the wider segments ML5W is greater than a width W51T of the thinner segments ML5T. In the present embodiments, the metal lines Vss_5 may also be referred to as metal pads or metal islands. Other details of the present embodiments are similar to those illustrated above, and therefore not repeated herein.

Based on the above discussions, it can be seen that the present disclosure offers advantages to the integrated circuit device. It is understood, however, that other embodiments may offer additional advantages, and not all advantages are necessarily disclosed herein, and that no particular advantage is required for all embodiments. One advantage is that a SRAM word line scheme is design by combining metal lines of plural metallization layers, thereby achieving lowered resistance and addressing the access time issues for high performance applications, which can further enhance performance and improve power management. Another advantage is that the SRAM word line scheme can robust metal resistance design window to achieve high speed applications.

According to some embodiments of the present disclosure, an integrated circuit device includes a first memory cell, a second memory cell, and an interconnect structure over the first and second memory cells. The interconnect structure includes a first metallization layer, a second metallization layer, and a third metallization layer. The first metallization layer includes a first word line electrically connected to the first memory cell and a second word line electrically connected to the second memory cell. The first and second word lines extend substantially along a first direction. The second metallization layer is above the first metallization layer. The second metallization layer includes a metal pad electrically connected to the first word line and a third word line electrically connected to the second word line, and the third word line extends substantially along the first direction. The third metallization layer is above the second metallization layer. The third metallization layer comprises a fourth word line electrically connected to the metal pad, and the fourth word line extends substantially along the first direction.

According to some embodiments of the present disclosure, an integrated circuit device includes a first memory cell, a second memory cell, and an interconnect structure. The interconnect structure is over the first and second memory cells. The interconnect structure includes a first metal line electrically connected to the first memory cell; a second metal line electrically connected to the second memory cell, wherein the second metal line is laterally aligned with the first metal line; a third metal line above the first metal line and electrically connected to first metal line; and a fourth metal line above the second metal line and electrically connected to the second metal line. The first to fourth metal lines extends substantially along a same direction, and the fourth metal line is higher than the third metal line.

According to some embodiments of the present disclosure, a method for fabricating an integrated circuit device is provided. The method includes forming a first pass-gate transistor and a second pass-gate transistor over a substrate; forming a first metallization layer over the first and second pass-gate transistors, wherein the first metallization layer comprises a first word line electrically connected to the first pass-gate transistor and a second word line electrically connected to the second pass-gate transistor; forming a second metallization layer over the first metallization layer; forming a third metallization layer over the second metallization layer, wherein the third metallization layer comprises a third word line electrically connected to the first word line through a first metal line of the third metallization layer and a metal pad electrically connected to the second word line through a second metal line of the third metallization layer; forming a fourth metallization layer over the third metallization layer; and forming a fifth metallization layer over the fourth metallization layer, wherein the fifth metallization layer comprises a fifth word line electrically connected to the metal pad through a metal line of the fourth metallization layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first memory cell;
a second memory cell; and
an interconnect structure over the first and second memory cells, wherein the interconnect structure comprises:
a first metallization layer comprising a first word line electrically connected to the first memory cell and a second word line electrically connected to the second memory cell, wherein the first and second word lines extend substantially along a first direction;
a second metallization layer above the first metallization layer, wherein the second metallization layer comprises a metal pad electrically connected to the first word line and a third word line electrically connected to the second word line, and the third word line extends substantially along the first direction; and
a third metallization layer above the second metallization layer, wherein the third metallization layer comprises a fourth word line electrically connected to the metal pad, and the fourth word line extends substantially along the first direction.

2. The integrated circuit device of claim 1, wherein a width of the metal pad is less than a width of the third word line.

3. The integrated circuit device of claim 1, wherein a length of the metal pad is less than a length of the third word line.

4. The integrated circuit device of claim 1, wherein a width of the metal pad is less than a width of the first word line.

5. The integrated circuit device of claim 1, wherein a width of the third word line is greater than a width of the first word line.

6. The integrated circuit device of claim 1, wherein a width of the fourth word line is greater than a width of the first word line.

7. The integrated circuit device of claim 1, further comprising:
a fourth metallization layer between the first metallization layer and the second metallization layer, wherein the fourth metallization layer comprises a plurality of metal lines extending substantially along a second direction orthogonal to the first direction.

8. The integrated circuit device of claim 7, further comprising:
a fifth metallization layer between the second metallization layer and the third metallization layer, wherein the fifth metallization layer comprises a plurality of metal lines extending substantially along the second direction.

9. The integrated circuit device of claim 1, wherein a width of the second word line is greater than a width of the first word line.

10. The integrated circuit device of claim 1, wherein the second metallization layer further comprises a power metal pad substantially aligned with the metal pad along the first direction.

11. The integrated circuit device of claim 1, wherein the third metallization layer further comprises a power metal pad, and the fourth word line has a first segment and a second segment, the first segment is closer to the power metal pad than the second segment, and the second segment is wider than the first segment.

12. The integrated circuit device of claim 1, wherein the first and second memory cells are static random-access memory (SRAM) cells.

13. An integrated circuit device, comprising:
a first memory cell;
a second memory cell; and
an interconnect structure over the first and second memory cells, wherein the interconnect structure comprises:
a first metal line electrically connected to the first memory cell;
a second metal line electrically connected to the second memory cell,
wherein the second metal line is laterally aligned with the first metal line;
a third metal line above the first metal line and electrically connected to first metal line; and
a fourth metal line above the second metal line and electrically connected to the second metal line, wherein the first to fourth metal lines extend substantially along a same direction, and the fourth metal line is higher than the third metal line.

14. The integrated circuit device of claim 13, wherein a width of the third metal line is greater than a width of the first metal line.

15. The integrated circuit device of claim 13, wherein a width of the fourth metal line is greater than a width of the second metal line.

16. The integrated circuit device of claim 13, further comprising:
a metal pad laterally aligned with the third metal line, wherein the metal pad is electrically connected with the fourth metal line and the second metal line.

17. The integrated circuit device of claim 16, wherein a width of the metal pad is greater than a width of the third metal line.

18. The integrated circuit device of claim 13, wherein the first and second memory cells are static random-access memory (SRAM) cells.

19. A method for fabricating an integrated circuit device, comprising:
forming a first pass-gate transistor and a second pass-gate transistor over a substrate;
forming a first metallization layer over the first and second pass-gate transistors, wherein the first metallization layer comprises a first word line electrically connected to the first pass-gate transistor and a second word line electrically connected to the second pass-gate transistor;
forming a second metallization layer over the first metallization layer;
forming a third metallization layer over the second metallization layer, wherein the third metallization layer comprises a third word line electrically connected to the first word line through a first metal line of the third metallization layer and a metal pad electrically connected to the second word line through a second metal line of the third metallization layer;
forming a fourth metallization layer over the third metallization layer; and
forming a fifth metallization layer over the fourth metallization layer, wherein the fifth metallization layer comprises a fifth word line electrically connected to the metal pad through a metal line of the fourth metallization layer.

20. The method of claim 19, further comprising:
forming a first contact plug over a gate electrode of the first pass-gate transistor; and
forming a second contact plug over a gate electrode of the second pass-gate transistor, wherein forming the first metallization layer is performed such that the first word line is in contact with the first contact plug, and the second word line is in contact with the second contact plug.
